(19) United States
(12) Patent Application Publication
(10) Pub. No.: US 2025/0239435 A1
(43) Pub. Date: Jul. 24, 2025

(54) SWITCHING CIRCUIT FOR MULTILEVEL PLASMA IMPEDANCE MATCHING

(71) Applicant: Applied Materials, Inc., Santa Clara, CA (US)

(72) Inventors: Anm Wasekul AZAD, Santa Clara, CA (US); Yue GUO, Redwood City, CA (US); Yang YANG, San Diego, CA (US); Kartik RAMASWAMY, San Jose, CA (US); Nicolas J. BRIGHT, Arlington, WA (US)

(21) Appl. No.: 18/418,206

(22) Filed: Jan. 19, 2024

(51) Int. Cl. H01J 37/32

(52) U.S. Cl. CPC H01J 37/32183; H01J 37/32146; H01J 2237/327; H01J 2237/3341

(57) ABSTRACT

Embodiments provided herein generally include apparatus, plasma processing systems and methods for tuning in a radio frequency (RF) plasma processing system for improving substrate processing metrics. Some embodiments are directed to an apparatus for processing a substrate in a plasma processing system. The apparatus generally includes: an impedance for a match circuit configured to perform impedance matching for a plasma load; a diode-based switch coupled to the impedance for the match circuit; at least one signal generator coupled to the diode-based switch and configured to bias the diode-based switch to a first position based on a first impedance generated in the plasma load; and a second position based on a second impedance generated in the plasma load and an RF signal generator configured to provide an RF signal to the plasma load.

### BACKGROUND

### Field

Embodiments of the present disclosure generally relate to a system and methods used in semiconductor device manufacturing. More specifically, embodiments of the present disclosure relate to a plasma processing system used to process a substrate.

### Description of the Related Art

Reliably producing high aspect ratio features is one of the key technology challenges for the next generation of semiconductor devices. One method of forming high aspect ratio features uses a plasma assisted etching process, such as a reactive ion etch (RIE) plasma process, to form high aspect ratio openings in a material layer, such as a dielectric layer, of a substrate. In a typical RIE plasma process, a plasma is formed in a processing chamber and ions from the plasma are accelerated towards a surface of a substrate to form openings in a material layer disposed beneath a mask layer formed on the surface of the substrate.

A typical RIE plasma processing chamber includes a radio frequency (RF) bias generator, which supplies an RF voltage to a power electrode. In a capacitive coupled gas discharge, the plasma is created by using an RF generator that is coupled to the power electrode that is disposed within an electrostatic chuck (ESC) assembly or within another portion of the processing chamber. Typically, an RF matching network (“RF match”) tunes an RF waveform provided from the RF generator to deliver RF power to an apparent load of 500 to minimize the reflected power and maximize the power delivery efficiency. If an impedance of the load is not properly matched to an impedance of a source (e.g., the RF generator), a portion of the forward delivered RF waveform can reflect back in an opposite direction along a same transmission line.

Therefore, there is a need for an apparatus and method for processing a substrate in a plasma processing system that solves the problems described above.

### SUMMARY

Embodiments provided herein generally include apparatus, plasma processing systems and methods for tuning in a radio frequency (RF) plasma processing system for improving substrate processing metrics.

Some embodiments are directed to an apparatus for processing a substrate in a plasma processing system. The apparatus generally includes: an impedance for a match circuit configured to perform impedance matching for a plasma load; a diode-based switch coupled to the impedance for the match circuit; at least one signal generator coupled to the diode-based switch and configured to bias the diode-based switch to a first position based on a first impedance generated in the plasma load and a second position based on a second impedance generated in the plasma load; and a radio frequency (RF) signal generator configured to provide an RF signal to the plasma load.

Some embodiments are directed to a method for processing a substrate in a plasma processing system. The method generally includes: generating a bias signal for a diode-based switch; adjusting a matching impedance for a plasma load by biasing the diode-based switch via the bias signal based on a PV waveform used to drive a plasma load; and providing an RF signal to the plasma load when the diode-based switch is biased using the bias signal.

Some embodiments are directed to a plasma processing system. The plasma processing system generally includes: a plasma chamber; an impedance for a match circuit configured to perform impedance matching for a plasma load associated with the plasma chamber; a diode-based switch coupled to the impedance for the match circuit; at least one signal generator coupled to the diode-based switch and configured to bias the diode-based switch to a first position based on a first impedance generated in the plasma load and a second position based on a second impedance generated in the plasma load; and an RF signal generator configured to provide a RF signal to the plasma load.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is a schematic representation of a plasma processing system, in accordance with certain embodiments of the present disclosure.

FIG. 1B is a schematic detailed cross-sectional view of the plasma processing system, in accordance with certain embodiments of the present disclosure.

FIG. 2 shows a voltage waveform that is established on a substrate due to a voltage waveform applied to an electrode of a processing chamber, in accordance with certain embodiments of the present disclosure.

FIGS. 3 and 4 illustrate switch control circuitry used to selectively reverse and forward bias a switch, in accordance with certain aspects of the present disclosure.

FIG. 5 illustrates switch control circuitry with a switch in a closed state using a forward bias signal, in accordance with certain aspects of the present disclosure.

FIG. 6 illustrates switch control circuitry with a switch in an open state using a reverse bias signal, in accordance with certain aspects of the present disclosure.

FIGS. 7A, 7B, and 7C illustrate an example technique for adjusting a matching impedance using a switch, in accordance with certain aspects of the present disclosure.

FIG. 8 is a process flow diagram illustrating a method for processing a substrate in a plasma processing system, in accordance with certain embodiments of the present disclosure.

FIG. 9 is a process flow diagram illustrating a method for processing a substrate in a plasma processing system, in accordance with certain embodiments of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to a system used in a semiconductor device manufacturing process. More specifically, embodiments provided herein generally include apparatus and methods for adjusting a matching impedance using a diode-based switch. For example, a switch may be implemented using Schottky diodes. If a Schottky diode is reverse-biased, the diode provides high impedance for a radio frequency (RF) signal, thereby blocking the RF signal. When forward-biased, the Schottky diode allows the RF signal to pass through as the diode acts as a shorted path under the influence of forward bias. In certain embodiments, one or more Schottky diodes may be configured as a switch that may be controlled via forward and reverse bias signals to adjust a matching impedance for a plasma load.

### Plasma Processing System Examples

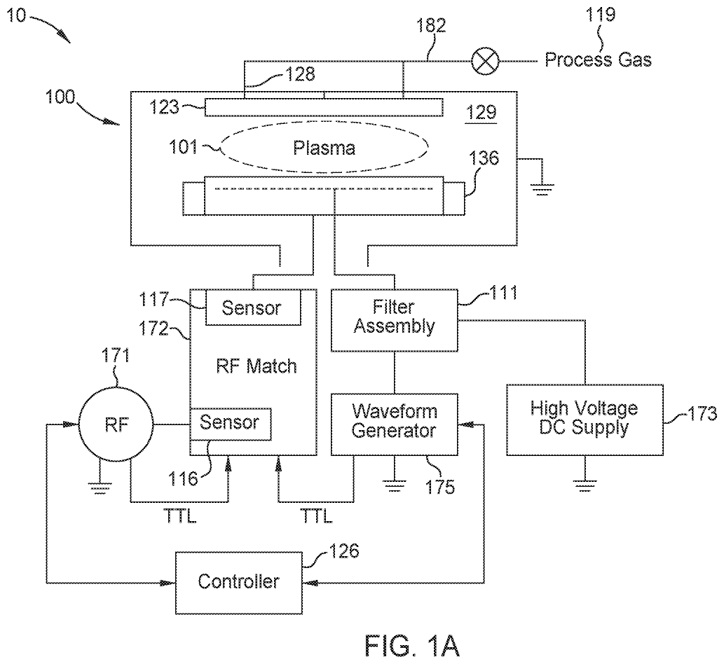

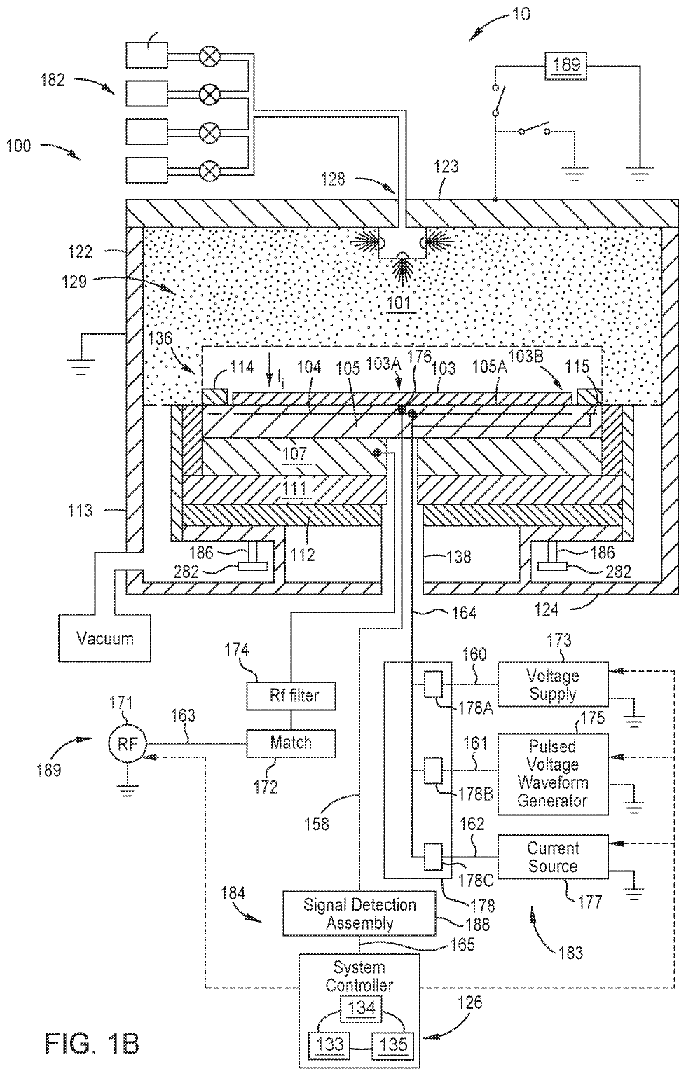

FIG. 1A is a schematic representation of a plasma processing system. The plasma processing system 10 is configured for plasma-assisted etching processes, such as a reactive ion etch (RIE) plasma processing. The plasma processing system 10 can also be used in other plasma-assisted processes, such as plasma-enhanced deposition processes (for example, plasma-enhanced chemical vapor deposition (PECVD) processes, plasma-enhanced physical vapor deposition (PEPVD) processes, plasma-enhanced atomic layer deposition (PEALD) processes, plasma treatment processing, plasma-based ion implant processing, or plasma doping (PLAD) processing. In one configuration, as shown in FIG. 1A, the plasma processing system 10 is configured to form a capacitive coupled plasma (CPP). However, in some embodiments, a plasma may alternately be generated by an inductively coupled source disposed over a processing region of the plasma processing system 10.

The plasma processing system 10 includes a processing chamber 100, a substrate support assembly 136, a gas delivery system 182, a high DC voltage supply 173, a radio frequency (RF) generator 171, and an RF match 172 (e.g., RF impedance matching network). A chamber lid 123 includes one or more sidewalls and a chamber base that are configured to withstand the pressures and energy applied to them while a plasma 101 is generated within a vacuum environment maintained in a processing volume 129 of the processing chamber 100 during processing.

The gas delivery system 182, which is coupled to the processing volume 129 of the processing chamber 100 is configured to deliver at least one processing gas from at least one gas processing source 119 to the processing volume 129 of the processing chamber 100. The gas delivery system 182 includes the processing gas source 119 and one or more gas inlets 128 positioned through the chamber lid 123. The gas inlets 128 are configured to deliver one or more processing gasses to the processing volume 129 of the processing chamber 100.

The processing chamber 100 includes an upper electrode (e.g., the chamber lid 123) and a lower electrode (e.g., the substrate support assembly 136) positioned in the processing volume 129 of the processing chamber 100. The upper and lower electrodes face one another. In one embodiment, the RF generator 171 is electrically coupled to the lower electrode. The RF generator 171 is configured to deliver an RF signal to ignite and maintain the plasma 101 between the upper and lower electrodes. In some alternative configurations, the RF generator 171 can also be electrically coupled to the upper electrode. For example, the RF generator 171 may deliver an RF source power to an RF baseplate within a cathode assembly (e.g., in the substrate support assembly 136) for plasma production, whereas the upper electrode is grounded. A center frequency of the RF source power can be from 13.56 MHz to very high frequency band such as 40 MHz, 60 MHz, 120 MHz or 162 MHz. In some examples, the RF source power can also be delivered through the upper electrode. The RF source power can be operated in a continuous mode or a pulsed mode. A pulsing frequency of the RF power can be from 100 to 10 kHz, and duty cycles are ranging from 5% to 95%. The RF generator 171 has a frequency tuning capability and can adjust its RF power frequency within e.g., ±5% or ±10%. In some embodiments, the RF generator 171 switches the RF power frequency at a predefined speed (e.g., two nanoseconds, fifty nanoseconds, etc.).

Referring to FIG. 1A and also FIG. 1B, which is a more detailed schematic cross-sectional view of the plasma processing system. The substrate support assembly 136 may be coupled to a high voltage DC supply 173 that supplies a chucking voltage thereto. The high voltage DC supply 173 may be coupled to a filter assembly 178 that is disposed between the high DC voltage supply 173 and the substrate support assembly 136.

The filter assembly 178 is configured to electronically isolate the high voltage DC supply 173 during plasma processing. In one configuration, a static DV voltage is between about −5000V and about 5000V, and is delivered using an electrical conductor (such as a coaxial power delivery line). The filter assembly 178 may include multiple filtering components or a single common filter.

The substrate support assembly 136 is coupled to a pulsed voltage (PV) waveform generator 175 configured to supply a PV to bias the substrate support assembly 136. The PV waveform generator 175 is coupled to the filter assembly 178. The filter assembly 178 is disposed between the PV waveform generator 175 and the substrate support assembly 136. The filter assembly 178 is configured to electronically isolate the PV waveform generator 175 during plasma processing.

The substrate support assembly 136 is coupled to the RF generator 171 configured to deliver an RF signal to the processing volume 129 of the processing chamber 100. The RF generator 171 is electronically coupled to the RF match 172 disposed between the RF generator 171 and the processing volume 129 of the processing chamber 100. For example, the RF match 172 is an electrical circuit used between the RF generator 171 and a plasma reactor (e.g., the processing volume 129 of the processing chamber 100) to optimize power delivery efficiency. One or more RF filters (e.g., within the RF match 172) are designed to only allow RF powers in a selected frequency range to pass, and to isolate RF power supplies from each other. In some cases, a bandwidth of an RF filter has to be larger than a frequency tuning range of the RF generator 171.

During the plasma processing, the RF generator 171 delivers an RF signal to the substrate support assembly 136 via the RF match 172. For example, the RF signal is applied to a load (e.g., gas) in the processing volume 129 of the processing chamber 100. If an impedance of the load is not properly matched to an impedance of a source (e.g., the RF generator 171), a portion of a waveform can reflect back in an opposite direction. Accordingly, to prevent a substantial portion of the waveform from reflecting back, some implementations find a match impedance (e.g., a matching point) by adjusting one or more components of the RF match 172 as the source and load impedances change.

The RF match 172 is electrically coupled to the RF generator 171, the substrate support assembly 136, and the PV waveform generator 175. The RF match 172 is configured to receive a synchronization signal from either or both of the RF generator 171 and the PV waveform generator 175.

The RF generator 171 and the PV waveform generator 175 are each directly coupled to a system controller 126. The system controller 126 synchronizes the respective generated RF signal and PV waveform.

Voltage and current sensors can be placed at an input and/or output of the RF match 172 to measure impedance and other parameters. These sensors can be synchronized using an external transistor-transistor logic (TTL) synchronization signal from an advanced waveform generator and/or RF generators or using measured voltage and current data to determine timing internally. For example, an output sensor 117 is configured to measure the impedance of the plasma processing chamber 100, and other characteristics such as the voltage, current, harmonics, phase, and/or the like. An input sensor 116 is configured to measure the impedance of the RF generator 171 and other characteristics such as the voltage, current, harmonics, phase, and/or the like. Based on either of the synchronization signals or the characteristics of the plasma processing chamber 100, the RF match 172 is able to capture fast impedance changes and optimize impedance matching.

The PV waveform generator 175 is used to supply a PV waveform and/or a tailored voltage waveform, which is a sum of harmonic frequencies associated with the waveform. The PV waveform generator 175 may output a synchronization TTL signal to the RF match 172. The voltage waveform is coupled to a bias electrode (e.g., a bias electrode 104 shown in FIG. 1B) through the filter assembly 178. The high DC voltage supply 173 is applied to chuck a substrate during a process for thermal control of the substrate. In some cases, there can be a third electrode at an edge of the cathode assembly for edge uniformity control.

FIG. 1B is a schematic detailed cross-sectional view of the plasma processing system 10. As shown in FIG. 11B, the plasma processing system 10 is configured to form a capacitively coupled plasma (CCP). However, in some embodiments, the plasma 101 may alternately be generated by an inductively coupled source disposed over the processing region of the plasma processing system 10. In this configuration, a coil may be placed on top of a ceramic lid (e.g., vacuum boundary) of the plasma processing chamber 100.

The plasma processing system 10 includes the processing chamber 100, the substrate support assembly 136, the gas delivery system 182, a DC power system 183, an RF power system 189, and the system controller 126. The processing chamber 100 includes a chamber body 113 that includes the chamber lid 123, one or more sidewalls 122, and a chamber base 124. The chamber lid 123, the one or more sidewalls 122, and the chamber base 124 collectively define the processing volume 129 of the processing chamber 100. The one or more sidewalls 122 and the chamber base 124 include materials (such as aluminum, aluminum alloys, or stainless steel alloys) that are sized and shaped to form a structural support for elements of the processing chamber 100 and are configured to withstand the pressures and added energy applied to them while the plasma 101 is generated within a vacuum environment maintained in the processing volume 129 of the processing chamber 100 during processing. A substrate 103 is loaded into, and removed from, the processing volume 129 of the processing chamber 100 through an opening (not shown) in one of the sidewalls 122. The opening is sealed with a slit valve (not shown) during plasma processing of the substrate 103.

The gas delivery system 182, which is coupled to the processing volume 129 of the processing chamber 100, includes the processing gas source 119 and the gas inlet 128 disposed through the chamber lid 123. The gas inlet 128 is configured to deliver one or more processing gases to the processing volume 129 of the processing chamber 100 from the processing gas source 119.

As noted above, the processing chamber 100 includes the upper electrode (e.g., the chamber lid 123) and the lower electrode (e.g., the substrate support assembly 136) disposed in the processing volume 129 of the processing chamber 100. The upper electrode and lower electrode are positioned to face each other. As seen in FIG. 1B, the RF generator 171 is electrically coupled to the lower electrode. The RF generator 171 is configured to deliver an RF signal to ignite and maintain the plasma 101 between the upper and lower electrodes. In some alternative configurations, the RF generator 171 can also be electrically coupled to the upper electrode.

The substrate support assembly 136 includes a substrate support 105, a substrate support base 107, an insulator plate 111, a ground plate 112, a plurality of lift pins 186, one or more substrate potential sensing assemblies 184 (e.g., including a signal detecting assembly 188), and a bias electrode 104. Each of the lift pins 186 are disposed through a through hole 185 formed in the substrate support assembly 136 and are used to facilitate the transfer of the substrate 103 to and from a substrate receiving surface 105A of the substrate support 105. The substrate support 105 is formed of a dielectric material. The dielectric material can include a bulk sintered ceramic material, a corrosion-resistant metal oxide (for example, aluminum oxide (Al₂O₃), titanium oxide (TiO), yttrium oxide (Y₂O₃), a metal nitride material (for example, aluminum nitride (AlN), titanium nitride (TiN)), mixtures thereof, or combinations thereof.

The substrate support base 107 is formed of a conductive material (for example aluminum, an aluminum alloy, or a stainless steel alloy). The substrate support base 107 is electrically isolated from the chamber base 124 by the insulator plate 111, and the ground plate 112 interposed between the insulator plate 111 and the chamber base 124. The substrate support base 107 is configured to regulate the temperature of both the substrate support 105, and the substrate 103 disposed on the substrate support 105 during substrate processing. The substrate support base 107 includes one or more cooling channels (not shown) disposed therein that are fluidly coupled to, and in fluid communication with, a coolant source (not shown), such as a refrigerant source or substrate source having a relatively high electrical resistance. The substrate support 105 includes a heater (not shown) to heat the substrate support 105 and the substrate 103 disposed on the substrate support 105.

The bias electrode 104 is embedded in a dielectric material of the substrate support 105. The bias electrode 104 is formed of one or more electrically conductive parts. The electrically conductive parts include meshes, foils, plates, or combinations thereof. The bias electrode 104 functions as a chucking pole (i.e., electrostatic chucking electrode) that is used to secure (e.g., electrostatically chuck) the substrate 103 to the substrate receiving surface 105A of the substrate support 105. A parallel plate like structure is formed by the bias electrode 104 and a layer of the dielectric material that is disposed between the bias electrode 104 and the substrate receiving surface 105A. The dielectric material can have an effective capacitance CE of between about 5 nF and about 50 nF. A layer of the dielectric material (e.g., aluminum nitride (AlN), aluminum oxide (Al₂O₃), etc.) has a thickness between about 0.3 mm and about 5 mm, such as between about 0.1 mm and about 3 mm, such as between about 0.1 mm and about 1 mm, or even between about 0.1 mm and 0.5 mm. The bias electrode 104 is electrically coupled to a clamping network, which provides a chucking voltage thereto. The clamping network includes the DC voltage supply 173 (e.g., a high voltage DC supply) that is coupled to a filter 178A of the filter assembly 178 that is disposed between the DC voltage supply 173 and the bias electrode 104. The filter 178A is a low-pass filter that is configured to block RF frequency and PV waveform signals provided by other biasing components found within the processing chamber 100 from reaching the DC voltage supply 173 during the plasma processing. The static DV voltage is between about −5000V and about 5000V, and is delivered using an electrical conductor (such as a coaxial power delivery line 106). The bias electrode 104 may bias the substrate 103 with the respect to the plasma 101 using one or more of the PV biasing schemes.

The substrate support assembly 136 includes an edge control electrode 115. The edge control electrode 115 is formed of one or more electrically conductive parts. The electrically conductive parts include meshes, foils, plates, or combinations thereof. The edge control electrode 115 is positioned below an edge ring 114 and surrounds the bias electrode 104 and/or is disposed a distance from a center of the bias electrode 104. For the processing chamber 100 that is configured to process circular substrates, the edge control electrode 115 is annular in shape, is made from a conductive material, and is configured to surround at least a portion of the bias electrode 104. As seen in FIG. 1B, the edge control electrode 115 is positioned within a region of the substrate support 105, and is biased by use of the PV waveform generator 175. The edge control electrode 115 is biased by use of a PV waveform generator that is different from the PV waveform generator 175 used for the bias electrode 104. The edge control electrode 115 is biased by splitting part of a signal provided from the PV waveform generator 175 to the bias electrode 104.

The DC power system 183 includes the DC voltage supply 173, the PV waveform generator 175, and a current source 177. The RF power system 189 includes the RF waveform generator 171, the RF matching circuit 172, and an RF filter 174. As shown in FIG. 1B, a power delivery line 163 electrically connects an output of the RF generator 171 to the RF matching circuit 172, the RF filter 174 and the substrate support base 107. As noted above, during the plasma processing, the DC voltage supply 173 provides a constant chucking voltage, while the RF generator 171 delivers the RF signal to the processing region, and the PV waveform generator 175 establishes the PV waveform at the bias electrode 104. For example, a sufficient amount of the RF power is applied to an RF bias voltage signal (which is also referred to herein as the RF waveform), and the RF waveform is provided to an electrode (e.g., the substrate support base 107) to cause the plasma 101 to be formed in the processing volume 129 of the processing chamber 100. The RF waveform has a frequency range between about 1 MHz and about 200 MHz, such as between 2 MHz and 40 MHz.

The DC power system 183 includes the filter assembly 178 to electrically isolate one or more of the components contained within the DC power system 183. A power delivery line 160 electrically connects an output of the DC voltage supply 173 to the filter assembly 178. A power delivery line 161 electrically connects the output of the PV waveform generator 175 to the filter assembly 178. A power delivery line 162 connects the output of the current source 177 to the filter assembly 178.

The current source 177 is selectively coupled to the bias electrode 104 by use of a switch (not shown) disposed in the power delivery line 162, to allow the current source 177 to deliver a desired current to the bias electrode 104 during one or more stages (e.g., ion current stage) of the voltage waveform generated by the PV waveform generator 175.

The filter assembly 178 includes multiple separate filtering components (i.e., discrete filters 178A-178C) that are each electrically coupled to an output node via a power delivery line 164. The filter assembly 178 may include one common filter electrically coupled to the output node via the power delivery line 164. The power delivery lines 160-164 include electrical conductors that include a combination of coaxial cables, such as a flexible coaxial cable that is connected in series with a rigid coaxial cable, an insulated high-voltage corona-resistant hookup wire, a bare wire, a metal rod, an electrical connector, of any combination of the above.

The system controller 126, also referred to herein as a processing chamber controller, includes a central processing unit (CPU) 133, a memory 134, and support circuits 135. The system controller 126 is used to control a process sequence used to process the substrate 103. The CPU is a computer processor configured for use in an industrial setting for controlling the processing chamber and sub-processors related thereto. The memory 134 described herein, which is generally non-volatile memory, can include random access memory, read-inly memory, hard disk drive, or other suitable forms of digital storage, local or remote. The support circuits 135 are coupled to the CPU 133 and include cache, clock circuits, input/output subsystems, power supplied, and the like, and combinations thereof. Software instructions (program) and data can be coded and stored within the memory 134 for instructing a processor within the CPU 133. A software program (or computer instructions) readable by the CPU 133 in the system controller 126 determines which tasks are performable by the components in the plasma processing system 10.

The program, which is readable by the CPU 133 in the system controller 126 includes code, which, when executed by the CPU 133, performs tasks relating to the plasma processing schemes described herein. The program may include instructions that are used to control the various hardware and electrical components within the plasma processing system 10 to perform the various process tasks and various process sequences used to implement the methods described herein. The program includes instructions that are used to perform one or more of the operations described herein.

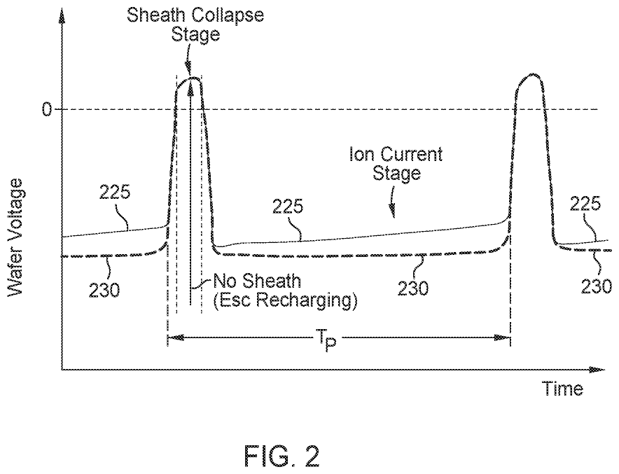

FIG. 2 illustrates two separate voltage waveforms established at the substrate 103 disposed on the substrate receiving surface 105A of the substrate support assembly 136 of the processing chamber 100 due to the delivery of PV waveforms to the bias electrode 104 of the processing chamber 100 by use of the PV waveform generator 175. A first waveform (e.g., a waveform 225) is an example of a non-compensated PV waveform established at the substrate 103 during the plasma processing. A second waveform (e.g., a waveform 230) is an example of a compensated PV waveform established at the substrate 103 by applying a negative slope waveform to the bias electrode 104 of the processing chamber 100 during an “ion current stage” portion of the PV waveform cycle by use of the current source 177. The compensated PV waveform can alternatively be established by applying a negative voltage ramp during the ion current stage of the PV waveform generated by the PV waveform generator 175. The PV waveform cycle of the waveforms 225, 230 each have a period Tₚ, which is, for example, typically between 2 microsecond (μs) and 10 μs, such as 2.5 μs. The ion current stage of the PV waveform cycle will typically take up between about 50% and about 95% of the period Tₚ, such as from about 80% to about 90% of the period Tₚ.

The waveforms 225 and 230 include two main stages: an ion current stage and a sheath collapse stage. Both portions (e.g., the ion current stage and the sheath collapse stage) of the waveforms 225 and 230, can be alternately and/or separately established at the substrate 103 during the plasma processing. At a beginning of the ion current stage, a drop in the voltage at the substrate 103 is created, due to the delivery of a negative portion of the PV waveform (e.g., the ion current portion) provided to the bias electrode 104 by the PV waveform generator 175, which creates a high voltage sheath above the substrate 103. The high voltage sheath allows the plasma generated positive ions to be accelerated towards the biased substrate 103 during the ion current stage, and thus, for RIE processes, controls the amount and characteristics of the etching process that occurs on the surface of the substrate 103 during the plasma processing. In some embodiments, it is desirable for the ion current stage to include a region of the PV waveform that achieves the voltage at the substrate 103 that is stable or minimally varying throughout the stage, as illustrated in FIG. 2 by the waveform 230. One will note that significant variations in the voltage established at the substrate 103 during the ion current stage, such as shown by the positive slope in the waveform 225, will undesirably cause a variation in the ion energy distribution (IED) and thus cause undesirable characteristics of the etched features to be formed in the substrate 103 during the RIE process.

Plasma sheath impedance varies with supplied PV waveform voltages. The RF match 172 can use either or both of the synchronization signals and/or use its internal sensors to sample impedances in different processing phases. In one example, a synchronization signal or characteristics determined by the input sensor 116 or the output sensor 117 are used to trigger the RF match 172 to determine at least two different impendences at different processing stages. Then, the RF match 172 updates its matching point based on the at least two different impedances.

Silicon Carbide (SiC)-based Schottky diodes exhibit low junction capacitance (e.g., in the order of tens of picofarads) when reverse-biased to a certain extent. If such a reverse-biased Schottky diode stack with low junction capacitance is placed in the path of an RF signal (e.g., having a frequency of 13.56 MHz), the diode provides high impedance for the RF signal, thereby blocking the RF signal. On the flip side, when forward-biased, the same Schottky diode stack allows the RF signal to pass through as the diode acts as a shorted path under the influence of forward bias. Therefore, the Schottky diode can act as an RF switch (RFS) by virtue of a circuit that can switch between the forward bias and the reverse bias states at the PV waveform frequency. This scheme allows a user to change the overall impedance of a matching network at a higher frequency than conventional implementations by turning on and off the RF switch using a reverse and forward bias. Traditional matching networks may be unable to tune at such high frequencies.

### Impedance Controlling Circuitry and System

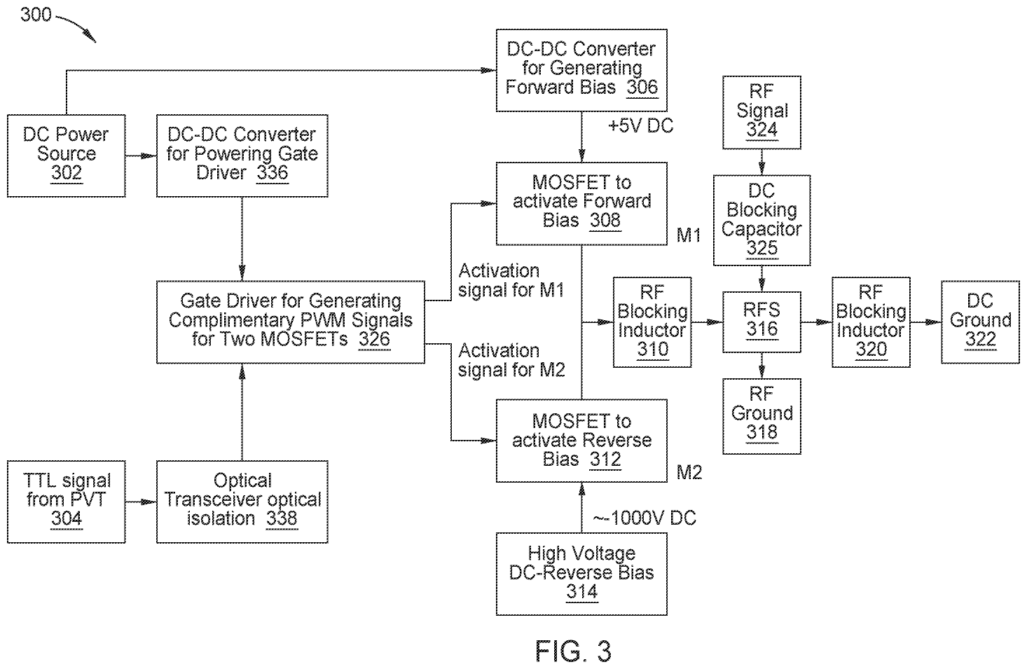

FIG. 3 illustrates switch control circuitry 300 used to selectively reverse and forward bias an RFS, in accordance with certain embodiments of the present disclosure. As shown, the circuitry 300 includes an RFS 316 which may be coupled between an RF signal generator 324 (e.g., corresponding to the generator 171 of FIG. 1B) and an RF ground node 318. A direct current (DC) blocking capacitor 325 may be coupled between the RF signal generator 324 and the RFS 316 to prevent (or at least reduce) DC bias signals from reaching the RF signal generator 324, such as, for example, the DC voltages generated by the high voltage DC supply 173.

The circuitry 300 may include a bias circuit for forward and reverse biasing the RFS, as described. For example, the bias circuit may include a signal generator 306 which may be implemented as a DC-to-DC converter for generating a forward bias signal (e.g., a 5V DC signal to be provided to the RFS 316 for forward biasing). The converter may receive a DC signal from a DC power source 302, based on which the forward bias signal may be generated. The forward bias signal may be selectively provided to the RFS 316 via a switch 308 (e.g., implemented via a metal-oxide-semiconductor field-effect transistor (MOSFET)) used to activate the forward bias of the RFS. As shown, an RF blocking network 310 (e.g., inductor, also referred to herein as an “RF attenuation circuit”) may be coupled between the switch 308 and the RFS 316 to prevent (or at least reduce) the RF signal (e.g., from generator 324) from reaching the bias circuit (e.g., reaching the generator 306).

The circuitry 300 may also include a DC revere bias signal generator 314 (e.g., providing a −1000V DC signal) to be supplied to the RFS 316 for reverse biasing the RFS. The reverse bias signal (e.g., from generator 314) may be selectively provided to the RFS 316 via a switch 312 (e.g., implemented via a MOSFET) used to activate the reverse bias of the RFS. The RF blocking network 310 may be coupled between the switch 312 and the RFS 316 to prevent (or at least reduce) the RF signal from reaching the generator 314.

To activate the switches 308, 312, the circuit 300 may include a gate driver (e.g., to drive the gate of the MOSFETs used to implement switches 308, 312). For example, the circuit 300 may include a DC-to-DC converter 336 for powering the gate driver 326. The converter 336 may generate a voltage to power the gate driver 326 based on a DC signal from the DC power source 302. The gate driver 326 may also receive a signal 304 representing the PV waveform (e.g., a transistor-transistor logic (TTL) signal) through an optical transceiver 338 for optical isolation. Based on the signal 304 and using the power from the converter 336, the gate driver 326 may provide activation signals to switches 308, 312 (e.g., M1 and M2 switches) to implement forward and reverse biasing of the RFS, as described herein.

The RFS 316 may be coupled between bias signal generators 306, 314 and a DC ground node 322. As shown, an RF blocking network 320 (e.g., inductor) may be coupled between the RFS and the DC ground node to prevent (or at least reduce) the RF signal from reaching the DC ground node 322.

FIG. 4 illustrates switch control circuitry 400 used to selectively reverse and forward bias the RFS, in accordance with certain embodiments of the present disclosure. As shown, the forward bias signal generator 306 may generate and provide a forward bias signal to the RFS through an RF blocking network 412 and the reverse bias signal generator 314 may be provided to the RFS 316 through an RF blocking network 416. While the switch control circuitry 300 described a common RF blocking network (e.g., RF blocking network 310) between the RFS and both of the forward and reverse bias generators, the switch control circuitry 400 uses separate RF blocking networks 412, 416, as shown.

The RF signal from generator 324 may be provided to the RFS, which may selectively allow the RF signal to pass across the RFS 316 to the RF ground node 318, as shown. In some embodiments, the RF ground node 318 is coupled to the RFS 316 through a dynamic load 317, which is created by the plasma 101 generated in the processing chamber 100. The RFS 316 may be implemented using parallel diode paths 450₁ to 450_{N} (collectively referred to as “diode paths 450”), N being a positive integer. For example, the RFS 316 may include multiple parallel diode paths 450, each path having multiple diodes coupled in series, such as the three diodes 452 of diode path 450₁. As shown, the forward or reverse bias signal may be provided to node 490 coupled to the anodes of the diodes of the RFS 316, which are coupled to the input line 316A of the RFS 316. The number of diodes 452 in each diode path can include one or more diodes 452, such as five or more diodes 452, or 10 or more diodes 452, or 50 or more diodes 452 that are coupled between the input line 316A and output line 316B of the RFS 316.

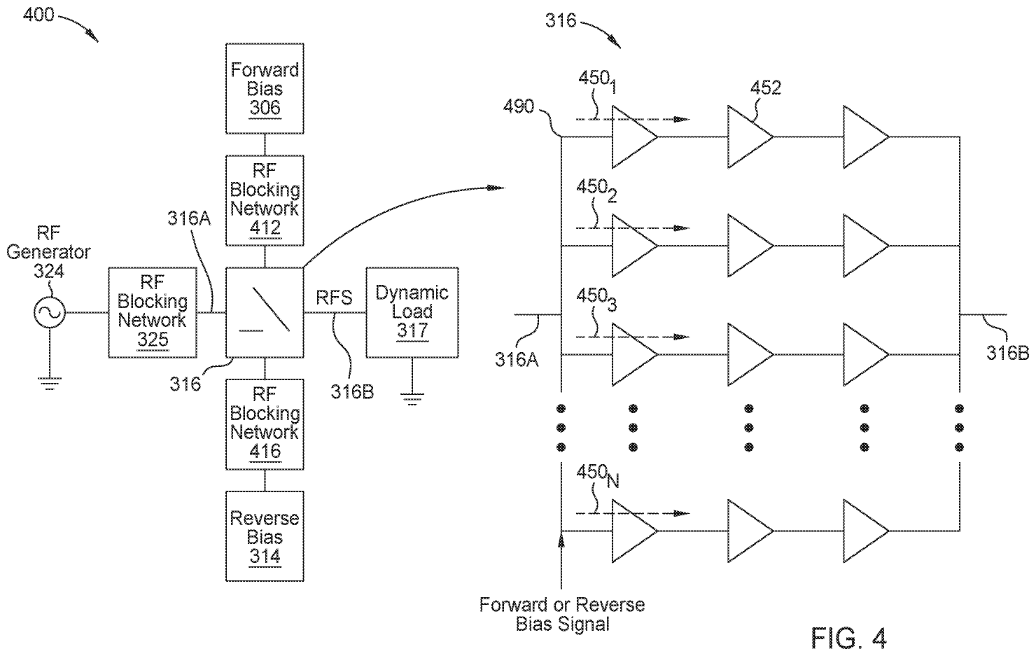

FIG. 5 illustrates switch control circuitry 400 with the RFS 316 in a closed state using a forward bias signal, in accordance with certain embodiments of the present disclosure. The RFS 316 is closed by providing a forward bias signal from the signal generator 306, where the reverse bias signal generator 314 is deactivated by causing the switch 308 of FIG. 3 to be closed and the switch 312 of FIG. 3 to be open. In one example, the forward bias signal will include applying a positive voltage to the node 490 (FIG. 4) and thus across the parallel diode paths. As shown, the RFS 316 is effectively a short circuit allowing the RF signal to pass through the input line 316A, parallel diode paths, and the output line 316B of the RFS 316.

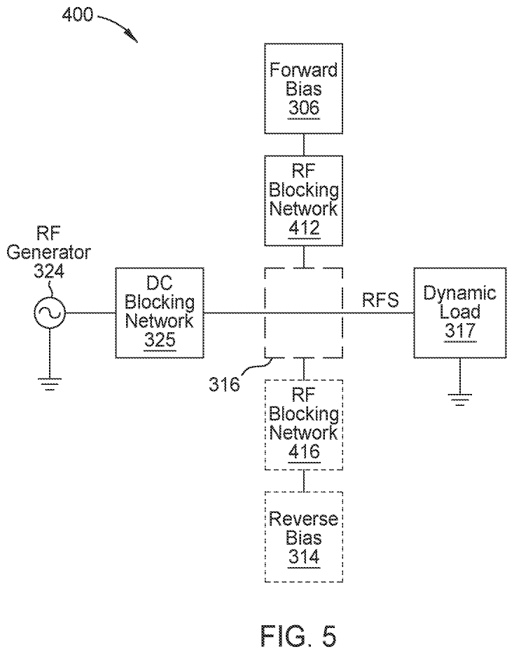

FIG. 6 illustrates switch control circuitry 400 with the RFS 316 in an open state using a reverse bias signal, in accordance with certain embodiments of the present disclosure. The RFS 316 is opened by providing a reverse bias signal from the signal generator 314, where the forward bias signal generator 306 is deactivated by causing the switch 308 of FIG. 3 to be open and the switch 312 of FIG. 3 to be closed. In one example, the reverse bias signal will include applying a negative voltage to the node 490 (FIG. 4) and thus across the parallel diode paths. As shown, the RFS 316 is effectively an open circuit preventing the RF signal from passing from the input line 316A to the output line 316B of the RFS 316.

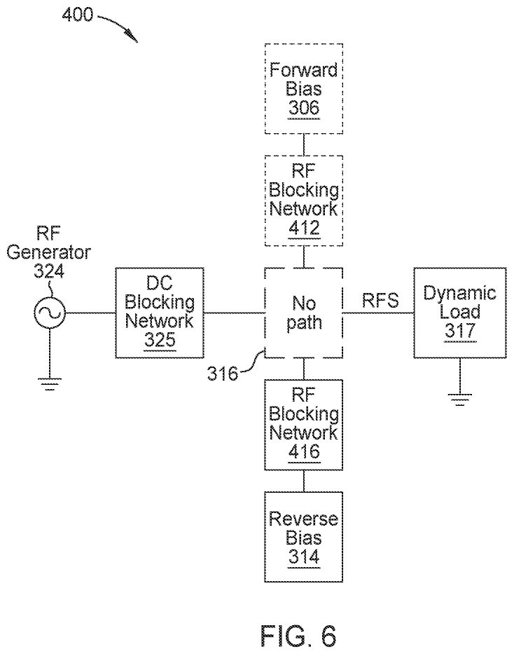

FIGS. 7A, 7B, and 7C illustrate an example technique for adjusting a matching impedance using the RFS 316, in accordance with certain embodiments of the present disclosure. As shown in FIG. 7A, an impedance adjustment path 704 may be coupled in parallel with the matching network 172 and coupled to the plasma generated dynamic load 750 as shown. The impedance adjustment path 704 may include a first impedance generating element, such as a capacitor 702 (e.g., variable capacitor) coupled in series with the RFS 316. In some embodiments, the capacitor 702 may be used to implement the DC block network 325 described herein.

As shown in FIG. 7B, when the RFS 316 is in a closed state (e.g., effectively a short circuit) using a forward bias signal created by the forward bias signal generator 306, the capacitor 702 is effectively in parallel with the matching network 172 providing a first matching impedance when a dynamic load 750 (e.g., plasma load) has a first impedance (labeled “impedance-1”). The dynamic load 750 may have the first impedance when the PV waveform is in an on-state (e.g., corresponding to the ion-current stage described with respect to FIG. 2), or in some cases, when the PV waveform is in an off-state (e.g., corresponding to the sheath collapse stage described with respect to FIG. 2).

As shown in FIG. 7C, the dynamic load 750 may have a second impedance (labeled “impedance-2”) when the PV waveform is in the off-state, or in some cases, when the PV waveform is in an on-state. In one example, the RFS 316 may be in an opened state (e.g., effectively an open circuit) using a reverse bias signal created by the reverse bias signal generator 314 so that the added parallel capacitance of the capacitor 702 does not impact the matching impedance in the off-state of the PV waveform, as shown.

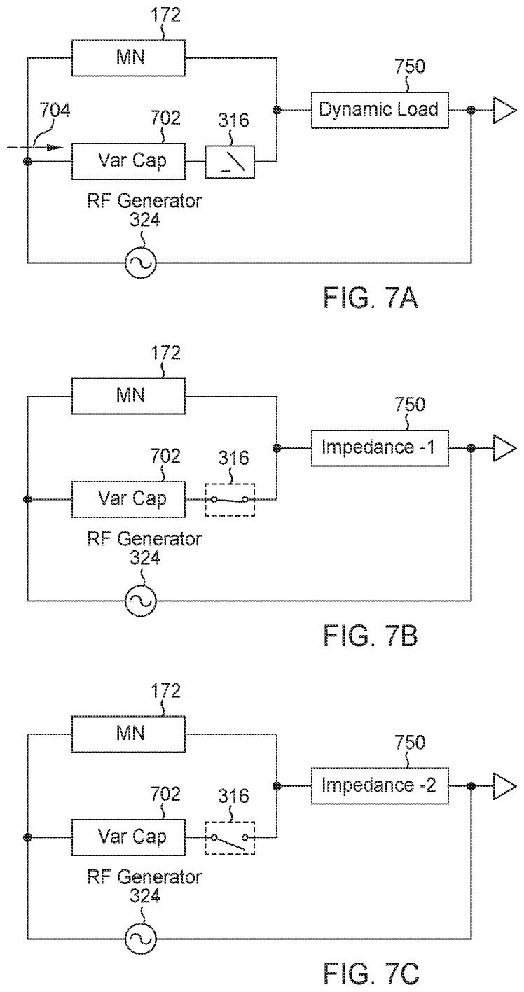

FIG. 8 is a process flow diagram illustrating a method 800 for processing a substrate in a plasma processing system, in accordance with certain embodiments of the present disclosure. The method 800 can be performed by a plasma processing system, such as the plasma processing system which may include the switch control circuitry 300 or switch control circuitry 400.

At operation 810, the plasma processing system generates a bias signal for a diode-based switch (e.g., RFS 316). The diode-based switch comprise one or more Schottky diodes. In some embodiments, the diode-based switch may include multiple diode paths (e.g., paths 450₁ to 450_{N} shown in FIG. 4) coupled in parallel, each of the multiple diode paths having one or more diodes (e.g., diodes 452).

At operation 820, the plasma processing system adjusts a matching impedance for a plasma load by biasing the diode-based switch via the bias signal based on a pulsed voltage (PV) waveform used to drive a plasma load. For example, adjusting the matching impedance may include providing, via a bias activation switch (e.g., switch 308 or switch 312 of FIG. 3), the bias signal to the diode-based switch.

At operation 830, the plasma processing system provides a radio frequency (RF) signal (e.g., via generator 324 of FIG. 3) to the plasma load when the diode-based switch is biased using the bias signal.

In some embodiments, the bias signal may be a forward bias signal. The plasma processing system may also generate a reverse bias signal and bias the diode-based switch via the reverse bias signal based on the PV waveform after generating the forward bias signal. The diode-based switch may be biased via the forward bias signal when the PV waveform is in a first state, and wherein the diode-based switch is biased via the reverse bias signal when the PV waveform is in a second state.

In some embodiments, an impedance (e.g., capacitor 702 shown in FIG. 7) and the diode-based switch may be on a first path and a match circuit (e.g., matching network 172) may be on a second path parallel to the first path. Adjusting the matching impedance may include opening or closing the diode-based switch via the bias signal.

### Plasma Processing Example

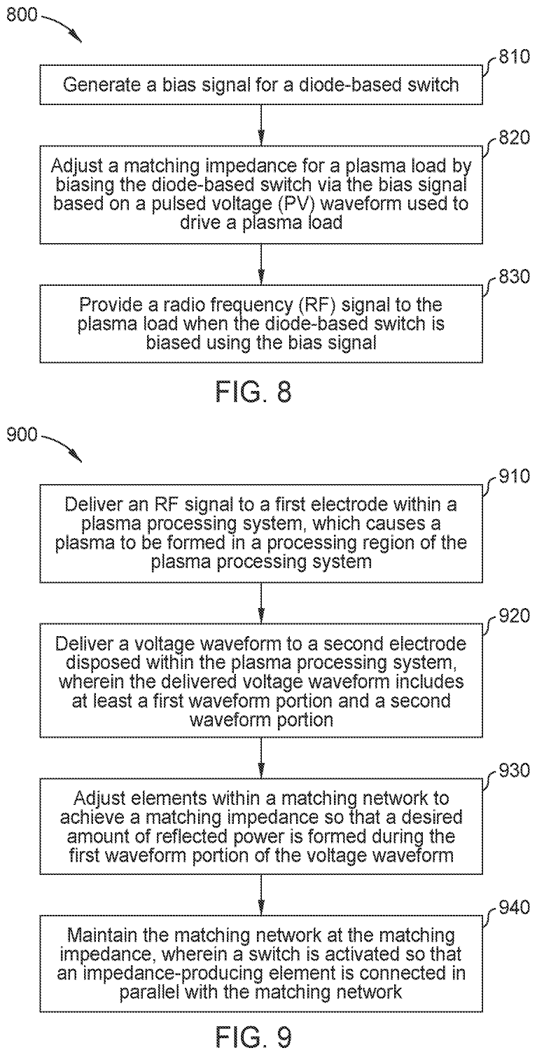

FIG. 9 is a process flow diagram illustrating a method 900 for processing a substrate in a plasma processing system, in accordance with certain embodiments of the present disclosure. The method 900 can be performed by a plasma processing system, such as the plasma processing system which may include the switch control circuitry 300 or switch control circuitry 400.

At operation 910, the RF signal generator 324 delivers an RF signal to a first electrode within a plasma processing system, which causes a plasma to be formed in the processing region of the plasma processing system. During operation 910, a matching network, which is coupled between the output of the RF signal generator 324 and the first electrode, adjusts elements within the matching network to achieve a first matching impedance so that a desired amount of reflected power is formed during the delivery of the RF signal to the first electrode.

At operation 920, the PV waveform generator 175 delivers a voltage waveform to a second electrode disposed within a plasma processing system, wherein the delivered voltage waveform includes at least a first waveform portion and a second waveform portion. In this example, the first waveform portion includes the application of a bias to the second electrode, and the second waveform portion includes the removal of the applied bias or an adjustment of the amount of the applied bias or type of the bias (i.e., negative or positive) applied to the second electrode. In some embodiments, the first and second electrodes are the same electrode within the plasma processing system, such as the bias electrode 104. In some other embodiments, the first and second electrodes are different electrodes within the plasma processing system.

At operation 930, while the RF signal generator 324 continues to deliver the RF signal to the first electrode and the first waveform portion of the voltage waveform is provided to the second electrode, the matching network adjusts the elements within the matching network to achieve a second matching impedance so that a desired amount of reflected power is formed during the first waveform portion of the voltage waveform. During operation 930, the RFS 316 may be in an opened state by use of a reverse bias signal created by the reverse bias signal generator 314 so that the impedance producing element (e.g., variable capacitor), which is in series with the RFS 316, does not impact the second matching impedance generated by the matching network.

At operation 940, while the RF signal generator 324 continues to deliver the RF signal to the first electrode and the second waveform portion of the voltage waveform is provided the second electrode by the PV waveform generator 175, the matching network is configured to maintain the matching network impedance at the second matching impedance and the RFS 316 is then activated such that it is placed in a closed state by the application of a forward bias signal created by the reverse bias signal generator 314. The activation of the RFS 316 is completed so that the impedance-producing element, which is connected in parallel with the matching network, will adjust the combined impedance generated by the matching network (e.g., second matching impedance) and the impedance-producing element (e.g., variable capacitor) to match or account for the change in the plasma impedance caused by the delivery of the second voltage portion of the voltage waveform versus the delivery of the first voltage portion of the voltage waveform.

Operations 930 and 940 can then be completed multiple times as the voltage waveform is being provided within the plasma processing system. The delivery of the voltage waveform and the operation of the RFS 316 are synchronized by use of the controller. As highlighted by this example, the RF switch (RFS) can be used to rapidly adjust the impedance formed within a system by use of the switch control circuitry described herein. In some embodiments, a plasma processing system may include a plurality of switch control circuitries that include differently configured impedance-generating elements, which have differing impedance-producing values, that are coupled with a matching network to allow for the formation of multiple different impedances that can be used at different times to achieve an impedance match during a plasma processing recipe performed during a plasma generation process.

While the foregoing is directed to embodiments of the present disclosure, other and further embodiments of the disclosure may be devised without departing from the basic scope thereof, and the scope thereof is determined by the claims that follow.

What is claimed is:

1. An apparatus for processing a substrate in a plasma processing system, comprising:
an impedance formed by a match circuit configured to perform impedance matching for a plasma load;
a diode-based switch coupled to the impedance of the match circuit;
at least one signal generator coupled to the diode-based switch and configured to bias the diode-based switch to a first position based on a first impedance generated in the plasma load and a second position based on a second impedance generated in the plasma load; and
a radio frequency (RF) signal generator configured to provide an RF signal to the plasma load.

2. The apparatus of claim 1, wherein the diode-based switch comprise one or more Schottky diodes.

3. The apparatus of claim 1, wherein the at least one signal generator comprises:
a forward bias signal generator; and
a reverse bias signal generator.

4. The apparatus of claim 3, wherein the forward bias signal generator is configured to provide a forward bias signal to bias the diode-based switch when a pulsed voltage (PV) waveform is in a first state, and wherein the reverse bias signal generator is configured to provide a reverse bias signal to bias the diode-based switch when the PV waveform is in a second state.

5. The apparatus of claim 3, further comprising:
a forward bias activation switch coupled between the forward bias signal generator and the diode-based switch; and
a reverse bias activation switch coupled between the reverse bias signal generator and the diode-based switch.

6. The apparatus of claim 1, further comprising at least one RF attenuation circuit coupled between the diode-based switch and the at least one signal generator.

7. The apparatus of claim 1, wherein the impedance is coupled between the RF signal generator and the diode-based switch.

8. The apparatus of claim 7, wherein the impedance comprises a capacitor.

9. The apparatus of claim 7, wherein the impedance is configured to attenuate direct current (DC) signals.

10. The apparatus of claim 1, wherein the diode-based switch comprises multiple diode paths coupled in parallel, each of the multiple diode paths having one or more diodes.

11. The apparatus of claim 1, wherein the impedance and the diode-based switch are on a first path, and wherein the match circuit is on a second path parallel to the first path.

12. The apparatus of claim 11, wherein the match circuit is coupled to the plasma load.

13. A method for processing a substrate in a plasma processing system, comprising:
providing a radio frequency (RF) signal to a plasma load formed in the plasma processing system, wherein the plasma load has a first impedance value and is formed using a match impedance and;
generating a bias signal for a diode-based switch;
adjusting the match impedance by biasing the diode-based switch via the bias signal based on the plasma load having a second impedance value.

14. The method of claim 13, wherein adjusting the match impedance comprises providing, via a bias activation switch, the bias signal to the diode-based switch.

15. The method of claim 13, wherein the diode-based switch comprise one or more Schottky diodes.

16. The method of claim 13, wherein
the first and second impedance values are formed by the delivery of a pulsed voltage waveform, and
the bias signal comprises a forward bias signal, the method further comprising:
generating a reverse bias signal; and
biasing the diode-based switch via the reverse bias signal based on the PV waveform after generating the forward bias signal.

17. The method of claim 16, wherein
the first impedance value is formed during a first state of the pulsed voltage waveform,
the second impedance value is formed during a second state of the pulsed voltage waveform,
the diode-based switch is biased via the forward bias signal when the PV waveform is in the first state, and
the diode-based switch is biased via the reverse bias signal when the PV waveform is in the second state.

18. The method of claim 13, wherein the diode-based switch comprises multiple diode paths coupled in parallel, each of the multiple diode paths having one or more diodes.

19. The method of claim 13, wherein an impedance and the diode-based switch are on a first path, wherein a match circuit is on a second path parallel to the first path, and wherein adjusting the match impedance comprises opening or closing the diode-based switch via the bias signal.

20. A plasma processing system, comprising:
a plasma chamber;
an impedance for a match circuit configured to perform impedance matching for a plasma load associated with the plasma chamber;
a diode-based switch coupled to the impedance for the match circuit;
at least one signal generator coupled to the diode-based switch and configured to bias the diode-based switch to a first position based on a first impedance generated in the plasma load and a second position based on a second impedance generated in the plasma load; and
a radio frequency (RF) signal generator configured to provide a RF signal to the plasma load.
